(19) United States
(12) Patent Application Publication
(10) Pub. No.: US 2026/0190939 A1
(43) Pub. Date: Jul. 2, 2026

(54) ELECTROSTATIC CHUCK E-SEAL WITH OFFSET SEALING SURFACE

(71) Applicant: LAM RESEARCH CORPORATION, Fremont, CA (US)

(72) Inventors: Behnam BEHZIZ, Newark, CA (US); Benny WU, Fremont, CA (US); Slobodan MITROVIC, Oakland, CA (US)

(21) Appl. No.: 19/126,060

(22) PCT Filed: Oct. 26, 2023
(86) PCT No.: PCT/US2023/036025

§ 371 Date: Apr. 30, 2025

Related U.S. Application Data
(60) Provisional application No. 63/422,660, filed on Nov. 4, 2022.

(51) Int. Cl. H10P 72/72

(52) U.S. Cl. CPC H10P 72/722

(57) ABSTRACT

A seal for a substrate support in a substrate processing system includes first and second annular seal portions each having upper and lower edges. The second seal portion is located radially outside of the first seal portion. A height of the first seal portion is greater than a height of the second seal portion such that the upper edge and the lower edge of the first seal portion are configured to form first sealing surfaces, the upper edge and the lower edge of the second seal portion are configured to form second sealing surfaces, and at least one of the second sealing surfaces is offset from a corresponding one of the first sealing surfaces in a vertical direction. A gap is defined between the first seal portion and the second seal portion. A horizontal connecting portion couples the first seal portion and the second seal portion.

### CROSS-REFERENCE TO RELATED APPLICATIONS

This application is a PCT International Application claiming the benefit of U.S. Provisional Application No. 63/422,660, filed on Nov. 4, 2022. The entire disclosure of the above application is incorporated herein by reference.

### FIELD

The present disclosure relates to substrate processing systems, and more particularly to systems and methods for protecting a bond layer of a substrate support.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

The substrate support may include a ceramic layer arranged to support the substrate. For example, the substrate may be clamped to the ceramic layer during processing. The ceramic layer may be bonded to a baseplate of the substrate support using a bonding material. The baseplate may comprise a cooled aluminum baseplate. For example, the bonding material, or bond, may include silicone with a filler, an epoxy matrix material, etc. The filler may comprise a metal oxide particle. The chemical composition of the bond and the filler may be selected to prevent inadvertent contamination of the process chamber.

### SUMMARY

A seal for a substrate support in a substrate processing system includes a first seal portion having an upper edge and a lower edge and a second seal portion having an upper edge and a lower edge. The first seal portion and the second seal portion are annular. The second seal portion is located radially outside of the first seal portion. A height of the first seal portion is greater than a height of the second seal portion such that the upper edge and the lower edge of the first seal portion are configured to form first sealing surfaces, the upper edge and the lower edge of the second seal portion are configured to form second sealing surfaces, and at least one of the second sealing surfaces is offset from a corresponding one of the first sealing surfaces in a vertical direction. A gap is defined between the first seal portion and the second seal portion. A horizontal connecting portion couples the first seal portion and the second seal portion.

In other features, the seal is “H”-shaped. The upper edges of the first seal portion and the second seal portion are offset from each other in the vertical direction, the lower edges of the first seal portion and the second seal portion are offset from each other in the vertical direction, or the upper edges of the first seal portion and the second seal portion are offset from each other in the vertical direction and the lower edges of the first seal portion and the second seal portion are offset from each other in the vertical direction. The seal is comprised of a perfluoroelastomer.

In other features, the seal further includes a barrier layer encapsulating at least one of the first seal portion and the second seal portion. The seal is comprised of a first material and the barrier layer is comprised of a second material having a greater resistance to erosion than the first material. The barrier layer is formed on radially outer surfaces of the second seal portion. An upper edge of the second seal portion is angled.

In other features, a substrate support includes the seal and further includes a baseplate, a ceramic layer, and a bond layer arranged between the baseplate and the ceramic layer. The seal encircles the bond layer between the baseplate and the ceramic layer. The substrate support further includes at least one of a first annular rim extending downward from a lower surface of the ceramic layer and a second annular rim extending upward from an upper surface of the baseplate. The first seal portion is located radially inward of the at least one of the first annular rim and the second annular rim and the second seal portion is located between the first annular rim and the upper surface of the baseplate, between the second annular rim and the lower surface of the ceramic layer, and between the first annular rim and the second annular rim.

In other features, the substrate support further includes a first annular rim extending downward from a lower surface of the ceramic layer and a second annular rim extending upward from an upper surface of the baseplate. The first seal portion is located radially inward of the first annular rim and the second annular rim and the second seal portion is located between the first annular rim and the second annular rim. The first seal portion and the second seal portion have different compression percentages. At least one of a gap between the bond layer and the first seal portion and a gap between the first seal portion and the second seal portion is filled with a sealing material. The sealing material comprises a grease or gel.

In other features, at least one of a lower surface of the first annular rim and an upper surface of the second annular rim is angled. A compression percentage of the second seal portion varies across the second seal portion in a radial direction. The substrate support further includes a notch defined in the lower surface of the ceramic layer. The upper edge of the first seal portion extends into the notch.

A substrate support for a substrate processing system includes a ceramic layer, a bond layer arranged between the baseplate and the ceramic layer, and an annular seal encircling the bond layer between the baseplate and the ceramic layer. The seal includes a first seal portion having an upper edge and a lower edge and a second seal portion having an upper edge and a lower edge. The second seal portion is located radially outside of the first seal portion. A height of the first seal portion is greater than a height of the second seal portion such that the upper edge and the lower edge of the first seal portion form first sealing surfaces with the baseplate and the ceramic layer, the upper edge and the lower edge of the second seal portion form second sealing surfaces with the baseplate and the ceramic layer, and each of the second sealing surfaces is offset from the first sealing surfaces in a vertical direction.

In other features, the substrate support further includes a gap defined between the first seal portion and the second seal portion and a horizontal connecting portion that couples the first seal portion and the second seal portion. The second seal portion is integrally formed with and directly adjacent to the first seal portion. The substrate support further includes a first annular rim extending downward from a lower surface of the ceramic layer and a second annular rim extending upward from an upper surface of the baseplate. The first seal portion is located radially inward of the first annular rim and the second annular rim. The second seal portion is located between the first annular rim and the second annular rim.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a substrate support according to the principles of the present disclosure;

FIG. 2A is an example seal for a substrate support according to the principles of the present disclosure;

FIG. 2B shows the example seal of FIG. 2A in more detail;

FIG. 3A shows another example embodiment of a seal according to the present disclosure;

FIG. 3B shows another example embodiment of a seal according to the present disclosure;

FIG. 3C shows another example embodiment of a seal according to the present disclosure;

FIG. 3D shows another example embodiment of a seal according to the present disclosure;

FIG. 3E shows another example embodiment of a seal according to the present disclosure;

FIG. 3F shows another example embodiment of a seal according to the present disclosure;

FIG. 3G shows another example embodiment of a seal according to the present disclosure;

FIG. 3H shows another example embodiment of a seal according to the present disclosure;

FIG. 3I shows another example embodiment of a seal according to the present disclosure; and

FIG. 3J shows another example embodiment of a seal according to the present disclosure.

In the drawings, reference numbers may be reused to identify similar and/or identical elements.

### DETAILED DESCRIPTION

A substrate support such as an electrostatic chuck (ESC) in a processing chamber of a substrate processing system may include a ceramic layer bonded to a conductive baseplate. The ceramic layer may be bonded to the baseplate using a bond or bond layer including a bonding material, filler, etc. The bond layer may be exposed to plasma, including radicals, ions, reactive species, etc., within the chamber at an outer edge of the substrate support. Exposure to the plasma may cause portions of the bond layer to erode (i.e., wear) over time. Such wear may allow chemical species and other substances (e.g., particles of the bond, the filler, etc.) to migrate into a reaction volume of the processing chamber, which may adversely affect substrate processing.

Various substrate supports may implement one or more techniques to minimize wear, to protect the bond layer, etc. to prevent wear and possible contamination of the processing chamber. In a first example, a substrate support may only include a bond layer for attaching the ceramic layer to the baseplate without implementing any additional techniques for preventing wear of the bond layer. In this example, plasma could erode the bond directly during substrate processing.

In a second example, the substrate support may include an ultra-pure, high modulus, epoxy layer arranged to protect the bond layer and prevent exposure of the bond to plasma. Typically, such an epoxy layer is not field-replaceable. However, the epoxy layer is relatively inflexible, and temperature changes in the substrate support may cause the bond layer to crack and/or delaminate over time and is subject to high erosion rates in oxygen and fluorine plasma chemistries. Accordingly, cracks between the ceramic layer and the epoxy layer and/or between the baseplate and the epoxy layer may allow erosion of the bond layer behind the epoxy layer.

In a third example, the substrate support may include an elastomer seal (an “e-seal”) such as a perfluoroelastomer seal arranged to protect the bond layer. However, conventional e-seals do not provide a permanent seal to protect the bond layer against plasma attack. Over time, conventional e-seals would gradually degrade and allow plasma radicals to attack the bond layer behind the e-seals. Depending on the operating conditions, some conventional e-seals may degrade rapidly and therefore need to be replaced frequently. Replacement of e-seals is a complex and expensive process, and improper replacement may lead to early failure of the substrate support, particle generation, and process non-uniformities. Further, some conventional e-seals rely on frictional forces to remain in position. When erosion damages the friction forces of the e-seal, the e-seal may shift its position and lose its sealing property.

Seal systems and methods according to the principles of the present disclosure are configured to form a secure seal between the bond layer and the plasma processing environment. For example, a seal (e.g., an e-seal) according to the present disclosure has an offset or asymmetrical (e.g., “H”-shaped) cross-section configured to withstand breakdown or erosion at a higher operating temperate, increase resistance to radicals, and facilitate self-alignment.

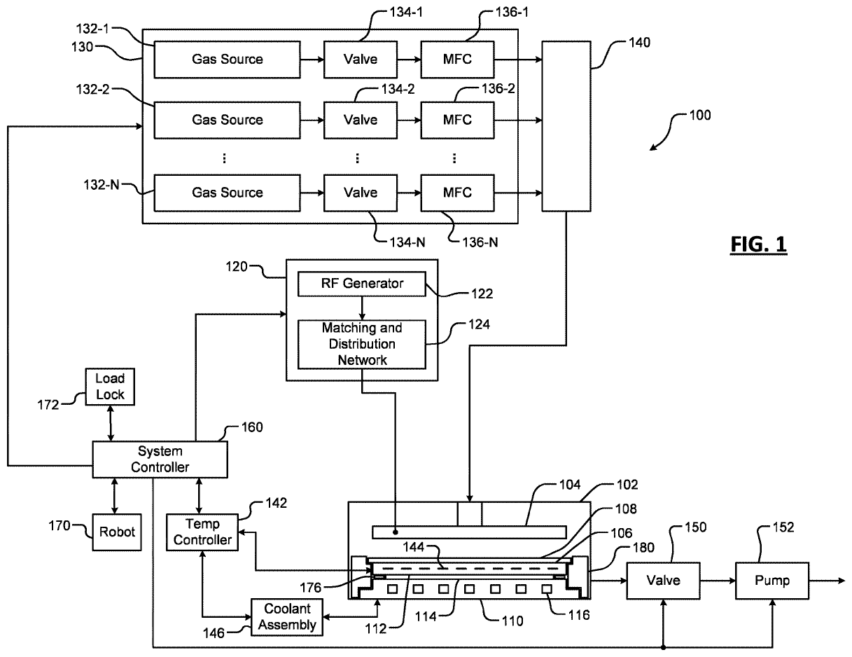

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The processing chamber 102 includes an upper electrode, which may include or correspond to a showerhead 104, and a substrate support 106, such as an electrostatic chuck (ESC). During operation, a substrate 108 is arranged on the substrate support 106. While a specific substrate processing system 100 and chamber 102 are shown as an example, the principles of the present disclosure may be applied to other types of substrate processing systems and chambers, such a substrate processing system that generates plasma in-situ, that implements remote plasma generation and delivery (e.g., using a microwave tube), etc.

The showerhead 104 introduces and distributes process gases. The showerhead 104 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode may include a conducting plate and the process gases may be introduced in another manner.

The substrate support 106 includes a conductive baseplate 110 that acts as a lower electrode. In some examples, the baseplate 110 may support a heating plate 112 (e.g., a ceramic layer), which may correspond to a ceramic multi-zone heating plate. A thermal resistance layer 114 (e.g., a bond layer) may be arranged between the heating plate 112 and the baseplate 110. The baseplate 110 may include one or more coolant channels 116 for flowing coolant through the baseplate 110.

An RF generating system 120 generates and outputs an RF voltage to one of the upper electrode (i.e., the showerhead 104) and the lower electrode (e.g., the baseplate 110 of the substrate support 106). The other one of the upper electrode and the baseplate 110 may be DC grounded, AC grounded or floating. For example only, the RF generating system 120 may include an RF voltage generator 122 that generates the RF voltage that is fed by a matching and distribution network 124 to the upper electrode or the baseplate 110. In other examples, the plasma may be generated inductively or remotely. Although, as shown for example purposes, the RF generating system 120 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more precursors and mixtures thereof. The gas sources may also supply purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 104.

A temperature controller 142 may be connected to a plurality of heating elements, such as thermal control elements (TCEs) 144 arranged in the heating plate 112. For example, the heating elements 144 may include, but are not limited to, macro heating elements corresponding to respective zones in a multi-zone heating plate and/or an array of micro heating elements disposed across multiple zones of a multi-zone heating plate. The temperature controller 142 may be used to control the plurality of heating elements 144 to control a temperature of the substrate support 106 and the substrate 108.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

The substrate support 106 includes a seal 176 arranged between the bond layer 114 and an edge ring system 180 of the substrate support 106. Although shown as a single component, the edge ring system 180 may be comprised of multiple ring structures, such as a bottom ring, middle, ring, and top ring. The seal 176 according to the present disclosure has an offset or asymmetrical cross-section as described below in more detail.

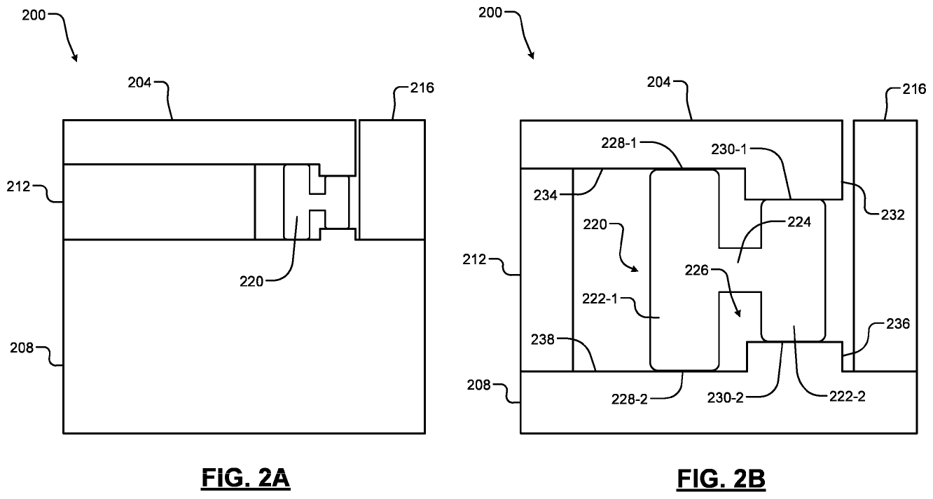

Referring now to FIGS. 2A and 2B, a portion of an example substrate support 200 is shown. The substrate support 200 includes a ceramic layer 204 arranged on a baseplate 208. In some examples, the ceramic layer 204 may correspond to a ceramic plate configured as a heating layer (e.g., a ceramic plate including embedded heating elements). A bond layer 212 is provided between the ceramic layer 204 and the baseplate 208. An edge ring 216 may be arranged around an outer edge of the ceramic layer 204 and the baseplate 208.

The substrate support 200 includes a seal 220 provided around a perimeter of the bond layer 212 between the ceramic layer 204 and the baseplate 208. For example, the seal 220 is an e-seal. The seal 220 has an offset or asymmetrical configuration (i.e., an offset or asymmetrical cross-section). For example, as shown, the seal 220 has a generally “H”-shaped cross-section. The seal 220 may be referred to as an H-shaped e-seal.

As shown in more detail in FIG. 2B, the seal 220 is comprised of first and second seal portions 222-1 and 222-2 each having first (e.g., upper) and second (e.g., lower) edges or ends, referred to collectively as the seal portions 222. The first seal portion 222-1 is disposed radially inward of the second seal portion 222-2. The seal portions 222 are each annular seals having a generally rectangular, vertical orientation. A horizontal connecting portion 224 couples the seal portions 222 together. For example, a gap 226 is defined between the first seal portion 222-1 and the second seal portion 222-2 and the connecting portion 224 extends through the gap 226 between the first seal portion 222-1 and the second seal portion 222-2. In some examples, the horizontal connecting portion 224 directly connects the seal portions 222 together. The seal portions 222 form two different sealing surfaces with the ceramic layer 204 and the baseplate 208 and therefore increase the effectiveness of the seal provided by the seal 220. The horizontal widths of the first and second portions 222-1, 222-2 and the connecting portion 224 may be wider or narrower than the depictions shown in FIGS. 2A-2B.

For example, the upper and lower edges of the first seal portion 222-1 form first sealing surfaces 228-1 and 228-2 (collectively, sealing surfaces 228) at interfaces with the ceramic layer 204 and the baseplate 208, respectively. Conversely, the upper and lower edges of the second seal portion 222-2 form second sealing surfaces 230-1 and 230-2 (collectively, sealing surfaces 230) at interfaces with the ceramic layer 204 and the baseplate 208, respectively, radially outward of the first sealing surfaces 228.

The offset configuration of the seal 220 causes at least one of the first sealing surfaces 228 and the second sealing surfaces 230 to be offset relative to others of the first sealing surfaces 228 and the second sealing surfaces 230. As shown, the second sealing surface 230-1 is offset from (e.g., lower than) the first sealing surface 228-1 and the second sealing surface 230-2 is offset from (e.g., higher than) the first sealing surface 228-2. As used herein, “offset” indicates that the two surfaces are not co-planar.

For example, a first annular rim 232 extends downward from a lower surface 234 of the ceramic layer 204 and a second annular rim 236 extends upward from an upper surface 238 of the baseplate 208. Accordingly, surfaces of the first annular rim 232 and the second annular rim 236 are offset from the lower surface 234 of the ceramic layer 204 and the upper surface 238 of the baseplate 208, respectively. In this manner, the second sealing surfaces 230 are offset from the first sealing surfaces 228. In other examples, the substrate support 200 may include only the first annular rim 232 or the second annular rim 236. Although shown as generally rectangular, in other examples the first annular rim 232 and/or the second annular rim 236 may have other shapes, such as convex, angled, trapezoidal, etc.

In some examples described below in more detail, the horizontal connecting portion 224 may be omitted. In other words, in these examples, the first seal portion 222-1 and the second seal portion 222-2 correspond to separate seals that still have the offset configuration shown in FIG. 2A.

In FIG. 2B, the first seal portion 222-1 is taller (i.e., has a greater length or height in a vertical direction) than the second seal portion 222-2. Accordingly, the second seal portion 222-2 is configured to be arranged between the first annular rim 232 and the second annular rim 236. In other words, the second seal portion 222-2 is aligned with the first annular rim 232 and the second annular rim 236. In other examples, the first annular rim 232 and the second annular rim 236 may be located radially inward of the location shown in FIG. 2B and the positions of the first seal portion 222-1 and the second seal portion 222-2 may be reversed. In other words, in some examples, the shorter seal portion and the annular rims may be located radially inward of the taller seal portion.

The offset sealing surfaces 228 and 230 form a serpentine or tortuous path from a plasma processing environment to the bond layer 212. Accordingly, reactive species must pass through both sealing surfaces 228 and 230 in a serpentine path to reach the bond layer 212 which significantly reduces exposure of the bond layer 212 to the reactive species.

Further, the annular rims 232, 236 form a mechanical barrier to retain the seal 220 between the ceramic layer 204 and the baseplate 208. In other words, any outward radial movement of the seal 220 is prevented by contact between the annular rims 232, 236 and the first seal portion 222-1. In this manner, the seal 220 is configured to be self-aligned around the bond layer 212 between the ceramic layer 204 and the baseplate 208. Further, because the annular rims 232 provide a mechanical barrier, the position of the seal 220 is not retained only by frictional force between surfaces of the seal 200 and surfaces of the ceramic layer 204 and the baseplate 208. Rather, retention of the seal 220 is determined based in part on a strength of the material of the seal 220. For example, as long as the material is sufficiently rigid to prevent the seal 220 from bowing outward or deforming (e.g., due to compression, thermal stress, etc.), the annular rims 232 prevent outward or inward movement of the seal 220. Accordingly, “walking” (e.g., shifting of position of the seal due to thermal expansion/stress, pressure changes, etc.) is reduced or eliminated.

In embodiments, the offset relationship between the first seal portion 222-1 and the second seal portion 222-2, as well as connection portion 224, facilitate installation and self-alignment of the seal 220. For example, the first seal portion 221-1 can be inserted between the annular rims 232 into the gap between the ceramic layer 204 and the baseplate 208. The connecting portion 224 allows at least some movement (e.g., angular movement) of the first seal portion 222-1 relative to the second seal portion 222-2 to facilitate insertion of the first seal portion 222-1 (e.g., an upper or lower edge of the first seal portion 221-1) into the gap. Once the first seal portion 222-1 is in position radially inward of the annular rims 232, the second seal portion 222-2 will necessarily be positioned between the annular rims 232.

In some examples, the first seal portion 222-1 and the second seal portion 222-2 have different compression percentages or ratios. For example, for large temperature range operation, seal materials may expand and contract. At an extreme low end of the temperature range, gaps may form at various sealing surfaces. Accordingly, one of the first seal portion 222-1 and the second seal portion 222-2 may have a greater compression percentage (i.e., may be compressed a greater amount) than the other. In this manner, contraction of the corresponding seal portion at low temperatures does not cause gaps to form.

Although shown as being substantially vertical, radially inner and outer sidewalls (e.g., a radially inner surface of the first seal portion 222-1 and a radially outer surface of the second seal portion 222-2) may have other shapes. In one example, the radially outer sidewall is concave to prevent outward buckling of the second seal portion 222-2. In other examples, either or both of the radially inner surface and the radially outer surface may be concave, convex, or combinations thereof.

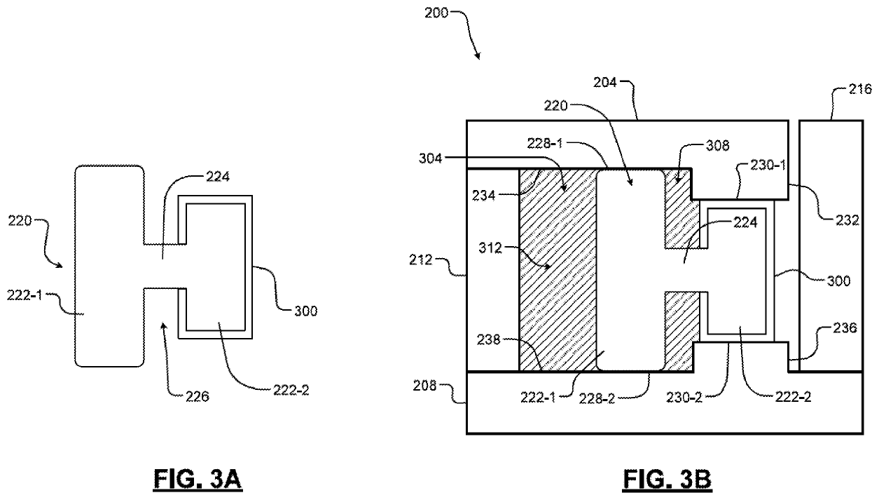

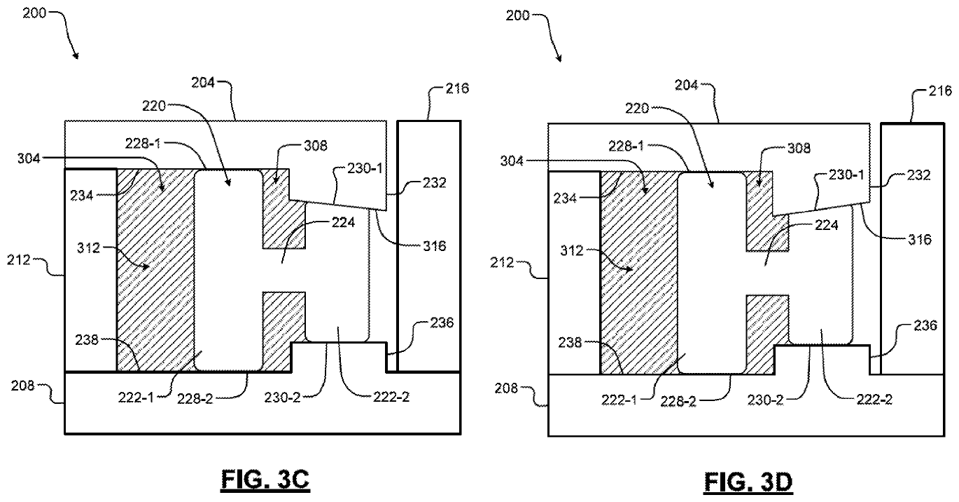

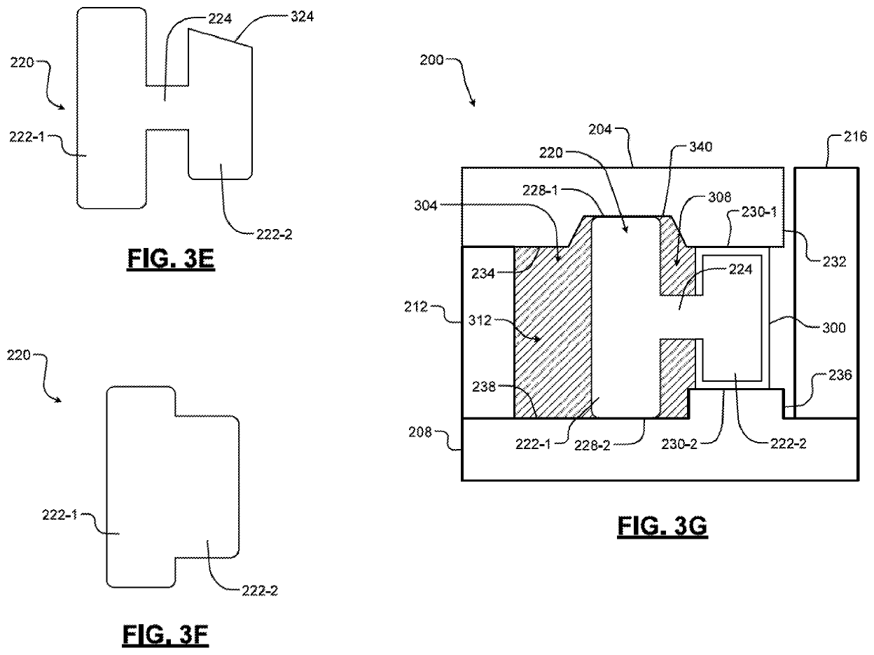

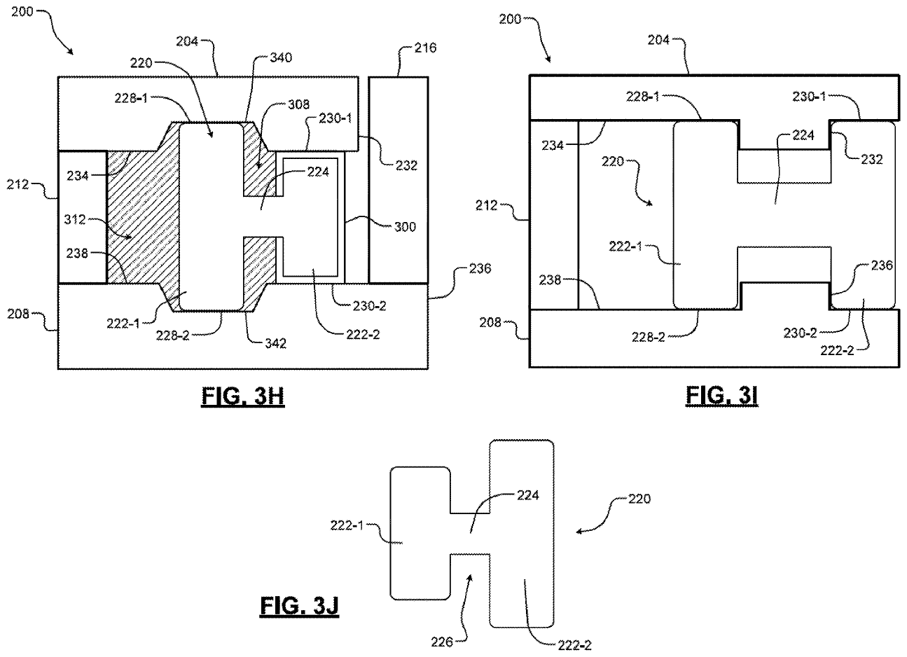

With continued reference to FIGS. 2A and 2B, various embodiments of the seal 220 according to the present disclosure are shown in FIGS. 3A, 3B, 3C, 3D, 3E, 3F, and 3G, 3H, 3I, and 3J. As shown in FIG. 3A, the seal 220 may be comprised of two or more different materials. For example, the seal 220 may include a coating or barrier layer 300. As shown, the barrier layer 300 encapsulates the second seal portion 222-2. In other examples, the barrier layer 300 may encapsulate the first seal portion 222-1 or both of the seal portions 222.

The barrier layer 300 is comprised of a different material than the seal 220. For example, the seal 220 may be comprised of a first material (e.g., a perfluoroelastomer, epoxy, etc.) while the barrier layer is comprised of a second material (e.g., Teflon, a G7 material, etc.). The second material has a greater resistance to reactive materials than the first material. In some examples, the second material partially covers the first material only on the surfaces most vulnerable to the plasma particle from the process chamber (e.g., radially outer surfaces of the first and second seal portions 222-1 and 222-2 and/or the top and bottom surfaces of 222-1 and 222-2). Accordingly, radially outer surfaces of the seal 220 exposed to the plasma processing environment have greater resistance to reactive materials. The barrier layer 300 may be included or omitted in any of the embodiments described herein.

As shown in FIG. 3B, in some embodiments, a volumes or gap 304 between the bond layer 212 and the first seal portion 222-1 and a volume or gap 308 between the first seal portion 222-1 and the second seal portion 222-2 may be filed with a sealing material 312, such as a sealing gel or grease. In some examples, the sealing material 312 may be disposed only in the gap 308.

As shown in FIG. 3C, a lower surface 316 of the first annular rim 232 may be angled or slanted. Although not shown in FIG. 3C, additionally or alternatively, an upper surface of the second annular rim 236 may be angled or slanted. The angled surface 316 facilitates retention of the position of the seal 220. Although as shown the angled surface 316 slopes downward in a radially outward direction, in other examples the angled surface 316 may slope upward in the radially outward direction (as shown in FIG. 3D). In still other examples, the lower surface 316 (or an upper surface of the second annular rim 236) may have other shapes, such as convex or concave.

Further, the angled surface 316 results in different compression percentages across the second seal portion 222-2 in a radial direction. In other words, since the angled surface 316 causes a width of a gap between the first annular rim 232 and the second annular rim 236 to vary, the compression percentages across the second seal portion 222-2 also vary. For example, in the example shown in FIG. 3C, a radially inner portion of the second seal portion 222-2 is compressed less (and has a smaller compression percentage) than a radially outer portion of the second seal portion 222-2. Conversely, in the example shown in FIG. 3D, the radially inner portion of the second seal portion 222-2 is compressed more (and has a greater compression percentage) than the radially outer portion of the second seal portion 222-2.

In this manner, the seal 220 has a greater temperature operation range as described above. For example, as temperatures decrease and the material of the seal 220 contracts, portions of the seal 220 having a relatively greater compression percentage will maintain sealing surfaces with the ceramic layer 204 and the baseplate 208 without allowing gaps to form.

In another example shown in FIG. 3E, an upper surface 324 of the second seal portion 222-2 is angled (e.g., angled downward in the radial outward direction). In other examples, additionally or alternatively, an upper surface of the second seal portion and/or upper and lower surfaces of the first seal portion 222-1 may be angled. In this manner, even if corresponding surfaces of the ceramic layer 204 and the baseplate 208 are not angled (i.e., are generally flat or horizontal), compression percentages of the second seal portion 222-2 or the first seal portion 222-1 may vary.

In another example shown in FIG. 3F, the horizontal connecting portion 224 is omitted and the second seal portion 222-2 is directly adjacent to the first seal portion 222-1. In other words, the first seal portion 222-1 and the second seal portion 222-2 are integrally formed and are not separated by a gap as shown in previous embodiments but still provide offset sealing surfaces. For example, installation/removal of the seal 220 including the connecting portion 224 may be simpler due to increased flexibility of the seal 220. Conversely, manufacturing of the seal 220 without the connecting portion 224 as shown in FIG. 3F may be easier due to the simpler design.

In another example shown in FIG. 3G, a notch 340 is defined (e.g., machined) into the lower surface 234 of the ceramic layer 204. An upper end or edge of the first seal portion 222-1 is received within the notch 340. In other words, the first sealing surface 228-1 of the ceramic layer 204 is located within the notch 340. In other examples, alternatively or additionally, a corresponding notch 342 may be defined in the upper surface 238 of the baseplate 208 as shown in FIG. 3H.

Accordingly, instead of extending downward from the lower surface 234 of the ceramic layer 204, the lower surface of the first annular rim 232 is generally coplanar with the lower surface 234 of the ceramic layer 204. Nonetheless, the sealing surfaces 228-1 and 230-1 are offset from one another and form a serpentine or tortuous path from the plasma processing environment to the bond layer 212. Further, the path from the plasma processing environment to the bond layer 212 above the seal 220 shown in FIG. 3G may be considered more tortuous than the corresponding path shown in previous embodiments. For example, to reach the bond layer 212, reactants would be required to penetrate upward into the notch 340, radially outward across the upper surface of the first seal portion 222-1, and back downward out of the notch 340. Accordingly, the path from the plasma processing environment to the bond layer 212 includes at least four changes of direction (relative to only two changes of direction as shown in FIGS. 2A and 2B).

In another example, shown in FIG. 3I, the second seal portion 222-2 is located radially outside of the first annular rim 232 and the second annular rim 236. Accordingly, the second sealing surfaces 230 are formed between upper and lower edges of the second seal portion 222-2 and respective surfaces of the ceramic layer 204 and the baseplate 208 radially outside of the first annular rim 232 and the second annular rim 236. The horizontal connecting portion 224 spans the gap between the first annular rim 232 and the second annular rim 232 to couple the seal portions 222 together. In some examples, the horizontal connecting portion 224 directly connects the seal portions 222 together. In some examples, one or more of the notches 340, 342 shown in FIG. 3H may be implemented in the example shown in FIG. 3I. In still another example shown in FIG. 3J, the first seal portion 222-1 is shorter than the second seal portion 222-2.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform, or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A seal for a substrate support in a substrate processing system, the seal comprising:
a first seal portion having an upper edge and a lower edge;
a second seal portion having an upper edge and a lower edge, wherein the first seal portion and the second seal portion are annular, the second seal portion is located radially outside of the first seal portion, and a height of the first seal portion is greater than a height of the second seal portion such that (i) the upper edge and the lower edge of the first seal portion are configured to form first sealing surfaces, (ii) the upper edge and the lower edge of the second seal portion are configured to form second sealing surfaces, and (iii) at least one of the second sealing surfaces is offset from a corresponding one of the first sealing surfaces in a vertical direction;
a gap defined between the first seal portion and the second seal portion; and
a horizontal connecting portion that couples the first seal portion and the second seal portion.

2. The seal of claim 1, wherein the seal is “H”-shaped.

3. The seal of claim 1, wherein (i) the upper edges of the first seal portion and the second seal portion are offset from each other in the vertical direction, (ii) the lower edges of the first seal portion and the second seal portion are offset from each other in the vertical direction, or (iii) the upper edges of the first seal portion and the second seal portion are offset from each other in the vertical direction and the lower edges of the first seal portion and the second seal portion are offset from each other in the vertical direction.

4. The seal of claim 1, wherein the seal is comprised of a perfluoroelastomer.

5. The seal of claim 1, further comprising a barrier layer encapsulating at least one of the first seal portion and the second seal portion, wherein the seal is comprised of a first material and the barrier layer is comprised of a second material having a greater resistance to erosion than the first material.

6. The seal of claim 5, wherein the barrier layer is formed on radially outer surfaces of the second seal portion.

7. The seal of claim 1, wherein the upper edge of the second seal portion is angled.

8. A substrate support comprising the seal of claim 1 and further comprising:
a baseplate;
a ceramic layer; and
a bond layer arranged between the baseplate and the ceramic layer,
wherein the seal encircles the bond layer between the baseplate and the ceramic layer.

9. The substrate support of claim 8, further comprising at least one of (i) a first annular rim extending downward from a lower surface of the ceramic layer and (ii) a second annular rim extending upward from an upper surface of the baseplate, wherein:
the first seal portion is located radially inward of the at least one of the first annular rim and the second annular rim; and
the second seal portion is located (i) between the first annular rim and the upper surface of the baseplate, (ii) between the second annular rim and the lower surface of the ceramic layer, and (iii) between the first annular rim and the second annular rim.

10. The substrate support of claim 8, further comprising:
a first annular rim extending downward from a lower surface of the ceramic layer; and
a second annular rim extending upward from an upper surface of the baseplate, wherein:
the first seal portion is located radially inward of the first annular rim and the second annular rim, and
the second seal portion is located between the first annular rim and the second annular rim.

11. The substrate support of claim 10, wherein the first seal portion and the second seal portion have different compression percentages.

12. The substrate support of claim 10, wherein at least one of a gap between the bond layer and the first seal portion and a gap between the first seal portion and the second seal portion is filled with a sealing material.

13. The substrate support of claim 12, wherein the sealing material comprises a grease or gel.

14. The substrate support of claim 10, wherein at least one of a lower surface of the first annular rim and an upper surface of the second annular rim is angled.

15. The substrate support of claim 14, wherein a compression percentage of the second seal portion varies across the second seal portion in a radial direction.

16. The substrate support of claim 8, further comprising a notch defined in the lower surface of the ceramic layer, wherein the upper edge of the first seal portion extends into the notch.

17. A substrate support for a substrate processing system, the substrate support comprising:
a baseplate;
a ceramic layer; ad
a bond layer arranged between the baseplate and the ceramic layer; and
an annular seal encircling the bond layer between the baseplate and the ceramic layer, the seal comprising
a first seal portion having an upper edge and a lower edge;
a second seal portion having an upper edge and a lower edge, wherein the second seal portion is located radially outside of the first seal portion and a height of the first seal portion is greater than a height of the second seal portion such that (i) the upper edge and the lower edge of the first seal portion form first sealing surfaces with the baseplate and the ceramic layer, (ii) the upper edge and the lower edge of the second seal portion form second sealing surfaces with the baseplate and the ceramic layer, and (iii) each of the second sealing surfaces is offset from the first sealing surfaces in a vertical direction.

18. The substrate support of claim 17, further comprising:
a gap defined between the first seal portion and the second seal portion; and
a horizontal connecting portion that couples the first seal portion and the second seal portion.

19. The substrate support of claim 17, wherein the second seal portion is integrally formed with and directly adjacent to the first seal portion.

20. The substrate support of claim 17, further comprising:
a first annular rim extending downward from a lower surface of the ceramic layer; and
a second annular rim extending upward from an upper surface of the baseplate, wherein:
the first seal portion is located radially inward of the first annular rim and the second annular rim, and
the second seal portion is located between the first annular rim and the second annular rim.
